(19) United States
(12) Patent Application Publication
(10) Pub. No.: US 2025/0218896 A1
(43) Pub. Date: Jul. 3, 2025

(54) HEAT DISSIPATION MEMBER, COOLING DEVICE, AND SEMICONDUCTOR MODULE

(71) Applicant: NIDEC CORPORATION, Kyoto (JP)

(72) Inventors: Kazuhiro NISHIKAWA, Kyoto (JP); Yuta HORI, Kyoto (JP); Kengo INOUE, Kyoto (JP)

(21) Appl. No.: 18/848,128

(22) PCT Filed: Mar. 7, 2023
(86) PCT No.: PCT/JP2023/008578

§ 371 Date: Sep. 18, 2024

(30) Foreign Application Priority Data
Mar. 24, 2022 (JP) 2022-048851

(51) Int. Cl. H01L 23/473

(52) U.S. Cl. CPC H01L 23/473

(57) ABSTRACT

A heat dissipation member to be installed in a liquid cooling jacket includes a base extending in a first direction of a refrigerant flow and a second direction, and having a thickness in a third direction, one or more fin groups arranged side by side in the first direction, the fin group including fins projecting from the base to one side in the third direction and arranged in the second direction, and a top plate at an end on one side in the third direction of the fin. A gap in the third direction is between the top plate and a top surface of the liquid cooling jacket. The top plate has first recessed portions recessed from a surface on one side in the third direction of the top plate to another side in the third direction and arranged side by side in the first direction.

### RELATED APPLICATIONS

The present application is a National Phase of International Application No. PCT/JP2023/008578 filed Mar. 7, 2023, which claims priority to Japanese Application No. 2022-048851, filed Mar. 24, 2022.

### TECHNICAL FIELD

The present disclosure relates to a heat dissipation member, a cooling device, and a semiconductor module.

### BACKGROUND ART

Conventionally, a heat dissipation member is used for cooling a heating element. The heat dissipation member includes a base portion and a plurality of fins. A plurality of the fins project from the base portion. The heat dissipation member can be installed in a liquid cooling jacket. The base portion and the liquid cooling jacket form a flow path. When a refrigerant flows through the flow path, heat of a heating element moves to the refrigerant (see, for example, Patent Literature 1).

### CITATIONS LIST

### Patent Literature

Patent Literature 1: JP 2020-53623 A

### SUMMARY OF INVENTION

### Technical Problems

Between a fin and a liquid cooling jacket, a certain gap (clearance) needs to be provided. If the gap is not provided, a fin may be deformed when a base portion is attached to the liquid cooling jacket, and there is a possibility that desired cooling performance cannot be obtained. Further, there is a possibility that a fin cannot be accommodated in the liquid cooling jacket due to positional variation when the fin is fixed to the base portion or assembly tolerance of the fin.

For this reason, a certain gap is provided in advance between the fin and the liquid cooling jacket. However, when a large amount of a refrigerant flows in this gap, an inflow amount of the refrigerant between the fins decreases, and there arises a problem that ability to cool the fin is lowered.

In view of the above circumstances, an object of the present disclosure is to provide a heat dissipation member capable of improving cooling performance in a configuration in which a gap is provided between a fin and a liquid cooling jacket.

### Solutions to Problems

An exemplary heat dissipation member of the present disclosure is a heat dissipation member that can be installed in a liquid cooling jacket, and includes a plate-shaped base portion that extends in a first direction along a direction in which a refrigerant flows and a second direction orthogonal to the first direction, and has thickness in a third direction orthogonal to the first direction and the second direction, one or a plurality of fin groups arranged side by side in the first direction, the fin group including a plurality of fins projecting from the base portion to one side in the third direction and arranged in the second direction, and a top plate portion provided at an end portion on one side in the third direction of the fin. A gap in the third direction is provided between the top plate portion and a top surface of the liquid cooling jacket that can be arranged on one side in the third direction of the top plate portion. The top plate portion has a plurality of first recessed portions that are recessed from a surface on one side in the third direction of the top plate portion to another side in the third direction and are arranged side by side in the first direction.

### Advantageous Effects of Invention

According to the exemplary heat dissipation member of the present disclosure, cooling performance can be improved in a configuration in which a gap is provided between the fin and the liquid cooling jacket.

### BRIEF DESCRIPTION OF DRAWINGS

FIG. 1 is a cross-sectional perspective view of a cooling device according to an exemplary embodiment of the present disclosure.

FIG. 2 is a perspective view of a heat dissipation member according to the exemplary embodiment of the present disclosure.

FIG. 3 is a side cross-sectional view of the heat dissipation member.

FIG. 4 is an enlarged view illustrating a configuration in the vicinity of a first fin in FIG. 3.

FIG. 5 is a schematic side view illustrating a first variation of a top plate portion.

FIG. 6 is a schematic side view illustrating a second variation of the top plate portion.

FIG. 7 is a schematic plan view of the heat dissipation member.

FIG. 8 is a perspective view illustrating a configuration in the vicinity of an upstream side fin group in the heat dissipation member.

FIG. 9 is an enlarged perspective view illustrating a configuration example of a single spoiler.

### DESCRIPTION OF EMBODIMENTS

Hereinafter, an exemplary embodiment of the present disclosure will be described with reference to the drawings.

Note that, in the drawings, with a first direction as an X direction, X1 indicates one side in the first direction, and X2 indicates another side in the first direction. The first direction is along a direction F in which a refrigerant W flows, and F1 indicates the downstream side and F2 indicates the upstream side. With a second direction orthogonal to the first direction as a Y direction, Y1 indicates one side in the second direction, and Y2 indicates another side in the second direction. With a third direction orthogonal to the first direction and the second direction as a Z direction, Z1 indicates one side in the third direction, and Z2 indicates another side in the third direction. Note that the above-described “orthogonal” also includes intersection at an angle slightly shifted from 90°. The above-described directions do not limit directions when a cooling device 110 and a heat dissipation member 1 are incorporated in various devices.

### 1. Configuration of Cooling Device

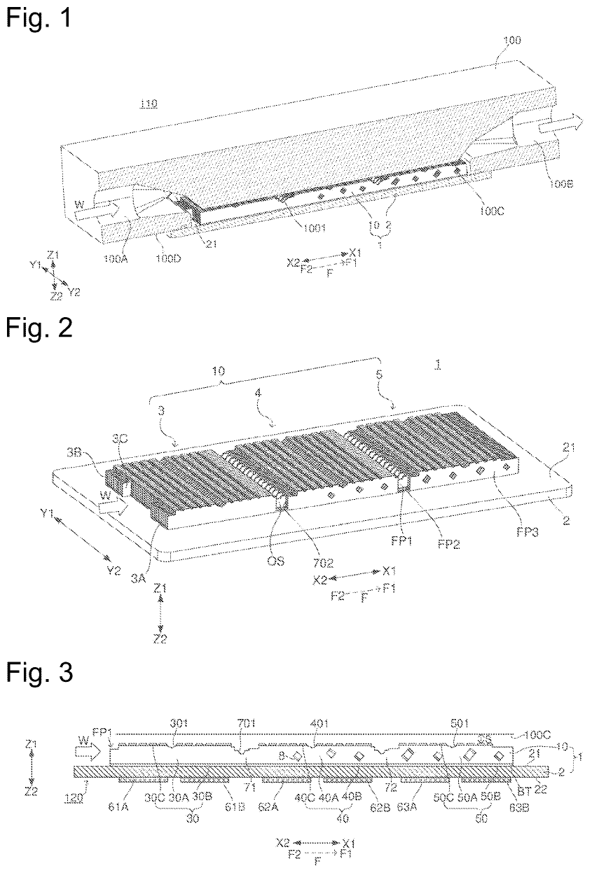

FIG. 1 is a cross-sectional perspective view of the cooling device 110 according to an exemplary embodiment of the present disclosure. The cooling device 110 includes the heat dissipation member 1 and a liquid cooling jacket 100 that accommodates the heat dissipation member 1. Note that FIG. 1 illustrates flow of the refrigerant W. One side in the first direction is the downstream side in a direction in which the refrigerant W flows, and another side in the first direction is the upstream side in the direction in which the refrigerant W flows. The refrigerant W is liquid such as water.

The heat dissipation member 1 includes a heat dissipation fin portion 10 and a base portion 2. The heat dissipation fin portion 10 is fixed to one side in the third direction with respect to the base portion 2. The liquid cooling jacket 100 includes an inlet flow path 100A arranged on another side in the first direction and an outlet flow path 100B arranged on one side in the first direction. The liquid cooling jacket 100 includes a top surface 100C arranged between the inlet flow path 100A and the outlet flow path 100B in the first direction.

In a state where the heat dissipation member 1 is not attached to the liquid cooling jacket 100, the top surface 100C is exposed to another side in the third direction. The heat dissipation member 1 is attached to the liquid cooling jacket 100 by fixing a surface 21 on one side in the third direction of the base portion 2 in the heat dissipation member 1 to a surface 100D on another side in the third direction of the liquid cooling jacket 100. In a state where the heat dissipation member 1 is attached, another side in the third direction of the top surface 100C is covered with the base portion 2, and a heat dissipation flow path 1001 is formed between the base portion 2 and the top surface 100C. The heat dissipation fin portion 10 is arranged inside the heat dissipation flow path 1001. The inlet flow path 100A, the heat dissipation flow path 1001, and the outlet flow path 100B are coupled in the first direction.

The refrigerant W flowing from the outside of the liquid cooling jacket 100 into the inlet flow path 100A flows inside the inlet flow path 100A to one side in the first direction and flows into the heat dissipation flow path 1001. The refrigerant W flowing through the heat dissipation flow path 1001 to one side in the first direction flows into the outlet flow path 100B and is discharged from the outlet flow path 100B to the outside of the liquid cooling jacket 100. A semiconductor device (not illustrated) (described later) is arranged on another side in the third direction of the base portion 2, and heat generated from the semiconductor device moves from the heat dissipation fin portion 10 to the refrigerant W flowing inside the heat dissipation flow path 1001, so that the semiconductor device is cooled.

### 2. Overall Configuration of Heat Dissipation Member

Next, the heat dissipation member 1 will be described in more detail. FIG. 2 is a perspective view of the heat dissipation member 1 according to an exemplary embodiment of the present disclosure. FIG. 3 is a side cross-sectional view of the heat dissipation member 1 as viewed from another side in the second direction to one side in the second direction. Note that FIG. 3 illustrates a state in which the heat dissipation member 1 is cut at an intermediate position in the second direction along a cut surface orthogonal to the second direction.

The heat dissipation member 1 is a device that cools a plurality of semiconductor devices 61A, 61B, 62A, 62B, 63A, and 63B (hereinafter, 61A and the like) (see FIG. 3) arranged in the first direction. The semiconductor devices 61A and the like are fixed to the heat dissipation member 1 to constitute a semiconductor module 120 (see FIG. 3). The semiconductor devices 61A and the like are an example of a heating element. The semiconductor devices 61A and the like are fixed to a surface 22 on another side in the third direction of the base portion 2. That is, the semiconductor module 120 includes the heat dissipation member 1 and at least one of the semiconductor devices 61A and the like arranged on another side in the third direction of the base portion 2.

The semiconductor devices 61A and the like are a power transistor of an inverter included in a traction motor for driving a wheel of a vehicle, for example. The power transistor is, for example, an insulated gate bipolar transistor (IGBT). In this case, the heat dissipation member 1 is mounted on the traction motor. The number of semiconductor devices may be more than one other than six, or may be one.

As described above, the heat dissipation member 1 can be installed in the liquid cooling jacket 100, and includes the base portion 2 and the heat dissipation fin portion 10. The heat dissipation fin portion 10 includes an upstream side fin group 3, a center fin group 4, and a downstream side fin group 5.

The base portion 2 has a plate shape that extends in the first direction and the second direction and has thickness in the third direction. The base portion 2 is made from metal having high thermal conductivity, such as a copper alloy.

The upstream side fin group 3, the center fin group 4, and the downstream side fin group 5 (hereinafter, the fin groups 3, 4, and 5) are arranged on one side in the third direction of the base portion 2 from another side (upstream side) in the first direction toward one side (downstream side) in the first direction in this order. As described later, the fin groups 3, 4, and 5 are fixed to the surface 21 on one side in the third direction of the base portion 2 by brazing, for example.

When viewed in the third direction, the semiconductor devices 61A and 61B overlap the upstream side fin group 3, the semiconductor devices 62A and 62B overlap the center fin group 4, and the semiconductor devices 63A and 63B overlap the downstream side fin group 5.

When the refrigerant W is supplied to the upstream side fin group 3 from a place further on the upstream side than the upstream side fin group 3, the refrigerant W sequentially flows through the fin groups 3, 4, and 5 and is discharged from the downstream side fin group 5 to the downstream side. At this time, heat generated from the semiconductor devices 61A and the like moves to the refrigerant W via the base portion 2 and the fin groups 3, 4, and 5. By the above, the semiconductor devices 61A and the like are cooled.

### 3. Method of Forming Fin Group

Here, an example of a specific method of forming the heat dissipation fin portion 10 (fin groups 3, 4, and 5) will be described with reference to FIGS. 2 and 3.

The fin groups 3, 4, and 5 are constituted as what is called a stacked fin by arranging a plurality of fin plates FP in the second direction. The fin plate FP is constituted by a metal plate extending in the first direction, and is constituted by, for example, a copper plate. Note that each of fin plates FP1, FP2, and FP3 illustrated in the diagram is a type of the fin plate FP. That is, FP is used as an overall reference sign for a fin plate.

FIG. 3 illustrates the first fin plate FP1. The first fin plate FP1 includes a first fin 30, a second fin 40, and a third fin 50 (hereinafter, fins 30, 40, and 50). The fins 30, 40, and 50 constitute the fin groups 3, 4, and 5, respectively.

The first fin 30 includes a side plate portion 30A, a bottom plate portion 30B, and a top plate portion 30C. The side plate portion 30A has a flat plate shape extending in the first direction and the third direction with a thickness direction in the second direction. The bottom plate portion 30B is formed by being bent from an end portion on another side in the third direction of the side plate portion 30A to another side in the second direction. The top plate portion 30C is formed by being bent from an end portion on one side in the third direction of the side plate portion 30A to another side in the second direction. That is, the top plate portion 30C is bent in the second direction at an end portion on one side in the third direction of the side plate portion 30A. Note that the top plate portion 30C is provided to be divided into one side in the first direction and another side in the first direction of a notch portion 301. The bottom plate portion 30B and the top plate portion 30C face each other in the third direction. By the above, the first fin 30 has a rectangular U-shaped cross section in a cross section orthogonal to the first direction.

Note that the bottom plate portion 30B and bottom plate portions 40B and 50B described later are a part of a bottom plate portion BT extending over the entire length in the first direction of the first fin plate FP1.

The second fin 40 is arranged on one side in the first direction of the first fin 30, and includes a side plate portion 40A, a bottom plate portion 40B, and a top plate portion 40C. Since a configuration of the second fin 40 is similar to the configuration of the first fin 30, detailed description of the configuration will be omitted here. The top plate portion 40C is provided to be divided into one side in the first direction and another side in the first direction of a notch portion 401 described later.

The third fin 50 is arranged on one side in the first direction of the second fin 40, and includes a side plate portion 50A, a bottom plate portion 50B, and a top plate portion 50C. Since a configuration of the third fin 50 is similar to the configuration of the first fin 30, detailed description of the configuration will be omitted here. The top plate portion 50C is provided to be divided into one side in the first direction and another side in the first direction of a notch portion 501 described later.

A coupling fin 71 is arranged between the first fin 30 and the second fin 40. The coupling fin 71 couples the fins 30 and 40 in the first direction. A coupling fin 72 is arranged between the second fin 40 and the third fin 50. The coupling fin 72 couples the fins 40 and 50 in the first direction.

Further, as to a configuration of the second fin plate FP2, a difference in configuration between the second fin plate FP2 and the first fin plate FP1 is that only a part of the bottom plate portion BT is arranged without the coupling fin 71 being arranged between the first fin 30 and the second fin 40, and only a part of the bottom plate portion BT is arranged without the coupling fin 72 being arranged between the second fin 40 and the third fin 50.

In the heat dissipation fin portion 10, the third fin plate FP3 (see FIG. 2) is arranged furthest on another side in the second direction, and the first fin plate FP1 and the second fin plate FP2 are alternately arranged in the second direction on one side in the second direction of the third fin plate FP3. Note that the third fin plate FP3 has a flat plate shape extending in the first direction and the third direction and having a thickness direction in the second direction. The third fin plate FP3 has a configuration in which a bottom plate portion and a top plate portion are removed from the second fin plate FP2. The third fin plate FP3 has a hole portion corresponding to a through hole 80 provided at a location where a spoiler 8 (described later) is formed in the fin plates FP1 and FP2, and is not provided with a spoiler.

Note that, as illustrated in FIG. 2, at the center in the second direction, the first fin 30 in the fin plates FP1 and FP2 does not have a portion projecting to another side in the first direction at an end portion on another side in the first direction. By the above, end portion fin groups 3A and 3B are formed at both end portions in the second direction at an end portion on another side in the first direction of the upstream side fin group 3. By the above, 3C recessed to another side in the third direction is formed between the end portion fin groups 3A and 3B (see FIG. 2).

By checking the recessed portion 3C, a worker can prevent an attachment direction error when attaching the heat dissipation member 1. Note that an end portion fin group may be formed at an end portion on one side in the first direction of the downstream side fin group 5, but is desirably provided in the upstream side fin group 3 as illustrated in FIG. 2. By providing the recessed portion 3C on the upstream side, it is possible to reduce flow path resistance on the center side in the second direction when the refrigerant W flows into the fin group 3, and improve cooling performance of cooling the semiconductor devices 61A and 61B located on the center side in the second direction in the fin group 3.

As described above, the heat dissipation fin portion 10 (fin groups 3, 4, and 5) are formed with various ones of the fin plates FP arranged in the second direction and integrated by, for example, riveting or the like. The formed heat dissipation fin portion 10 is fixed to the surface 21 on one side in the third direction of the base portion 2 by brazing, for example. As described above, by constituting the heat dissipation fin portion 10 by using the fin plate FP having a configuration in which the fins 30, 40, and 50 are integrated in the first direction, it is possible to increase rigidity of the heat dissipation member 1 and prevent deflection on the base portion 2 due to water pressure of the refrigerant W also in a case where thickness of the base portion 2 is reduced for thermal conductivity.

Note that, as illustrated in FIG. 3, in the first fin plate FP1, the coupling fin 71 is formed between the first fin 30 and the second fin 40, and a recessed portion 701 recessed to another side in the third direction is formed on one side in the third direction of the coupling fin 71. Further, in the second fin plate FP2, between the first fin 30 and the second fin 40, a coupling fin is not formed and a recessed portion 702 (see FIG. 2) is formed. The recessed portion 702 is recessed to another side in the third direction down to the bottom plate portion BT. The recessed portions 701 and 702 formed as described above form an open slot OS. The open slot OS has an effect of stopping growth of a boundary layer in a fin to improve cooling performance, an effect of mixing the refrigerant W discharged from a downstream side outlet of the fin group 3 and having temperature distribution in the second direction, and an effect of reducing a pressure loss. Note that, by providing the coupling fin 71, it is possible to improve rigidity of the heat dissipation member 1, and increase a contact area with the refrigerant W in the open slot OS to improve cooling performance. Note that such a configuration is similar to a configuration between the fin groups 4 and 5.

Further, the heat dissipation fin portion 10 is divided into the fin groups 3, 4, and 5 by the open slot as described above, but may include only one fin group without providing the open slot.

In other words, the heat dissipation member 1 includes one or a plurality of the fin groups 3, 4, and 5 arranged side by side in the first direction constituted by a plurality of the fins 30, 40, and 50 projecting from the base portion 2 to one side in the third direction arranged side by side in the second direction, and the top plate portions 300, 40C, and 50C provided at an end portion on one side in the third direction of the fins 30, 40, and 50.

### 4. Configuration of Top Plate Portion

In a state where the heat dissipation member 1 is attached to the liquid cooling jacket 100, as illustrated in FIG. 3, the top surface 100C (see FIG. 1) of the liquid cooling jacket 100 is arranged on one side in the third direction of the top plate portions 300, 40C, and 50C, and faces the top plate portions 300, 40C, and 50C in the third direction. A gap S in the third direction is provided between the top plate portions 300, 40C, and 50C and the top surface 100C. That is, the gap S in the third direction is provided between the top plate portions 30C, 40C, and 50C and the top surface 100C of the liquid cooling jacket 100 that can be arranged on one side in the third direction of the top plate portions 300, 40C, and 50C.

In a case where a gap (clearance) is provided between a fin and a top surface of a liquid cooling jacket like the gap S, if a large amount of a refrigerant flows in the gap, a flow rate of a refrigerant flowing between fins decreases, and ability to cool a fin with a refrigerant is lowered. As compared with the case where a fin is not provided with a top plate portion as in the present embodiment, flow path resistance of the gap increases, and thus a flow rate of a refrigerant flowing between fins increases. In the present embodiment, the top plate portion is further improved as described below.

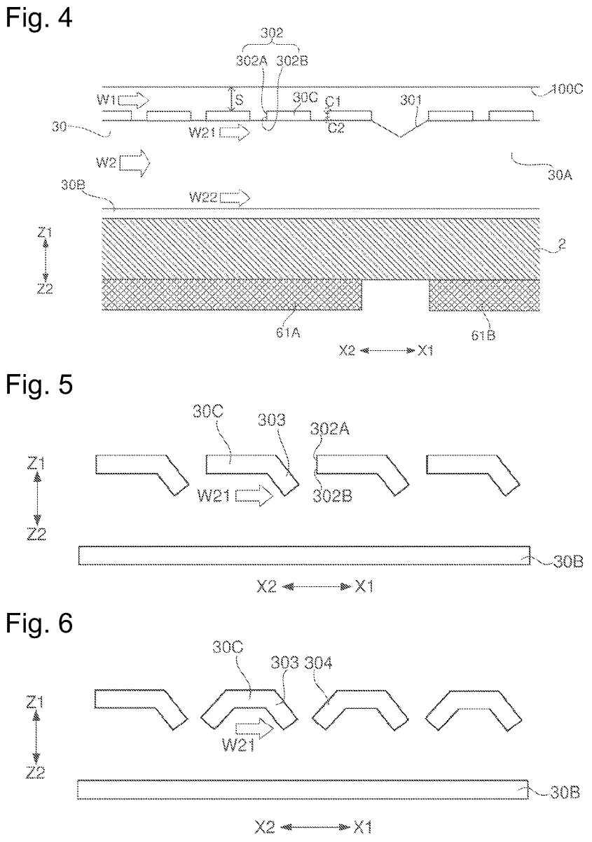

FIG. 4 is an enlarged view illustrating a configuration in the vicinity of the first fin 30 in FIG. 3. As illustrated in FIG. 4, the top plate portion 30C is provided with a slit (through hole) 302 penetrating in the third direction. A plurality of the slits 302 are provided in the first direction. The slit 302 has a first recessed portion 302A recessed to another side in the third direction and a second recessed portion 302B recessed to one side in the third direction.

That is, the top plate portion 30C has a plurality of the first recessed portions 302A that are recessed from a surface on one side in the third direction of the top plate portion 30C to another side in the third direction and are arranged side by side in the first direction. By providing the first recessed portion 302A, turbulent flow is generated in a refrigerant W1 flowing through the gap S due to a corner portion C in the first recessed portion 302A, and flow path resistance in the gap S increases. As a result, a flow rate of a refrigerant flowing from the most upstream side into a flow path between the side plate portions 30A adjacent to each other in the second direction increases, and a flow rate of a refrigerant W2 flowing between the fins 30 increases. By the above, ability to cool the fin 30 with a refrigerant is improved, and cooling performance for cooling the semiconductor devices 61A and 61B can be improved.

Furthermore, the top plate portion 30C has a plurality of the second recessed portions 302B that are recessed from a surface on another side in the third direction of the top plate portion 30C to one side in the third direction and are arranged side by side in the first direction. Due to a corner portion C2 in the second recessed portion 302B, turbulent flow is generated in a refrigerant W21 flowing in the vicinity of the second recessed portion 302B on another side in the third direction of the top plate portion 30C. For this reason, flow velocity distribution in the third direction is generated between the fins 30, and a refrigerant W22 flows preferentially in a region farther toward the base portion 2 than the vicinity of the second recessed portion 302B. By the above, the semiconductor devices 61A and 61B arranged on another side in the third direction of the base portion 2 can be easily cooled.

The first recessed portion 302A and the second recessed portion 302B are coupled in the third direction. By the above, the recessed portions 302A and 302B can be easily formed by forming the slit 302 penetrating in the third direction.

Further, since the top plate portion 30C is bent in the second direction at an end portion on one side in the third direction of the side plate portion 30A and can be easily formed by press working, the first recessed portion 302A can be easily formed.

Note that the top plate portions 40C and 50C of the fins 40 and 50 can also achieve a similar effect by a similar configuration to the top plate portion 30C.

### 5. Variation of Top Plate Portion

FIG. 5 is a schematic side view illustrating a first variation of the top plate portion 30C. In the present variation, the top plate portion 30C includes a bent portion 303 that is bent toward another side in the third direction at an end portion on another side in the first direction of the first recessed portion 302A and the second recessed portion 302B.

FIG. 6 is a schematic side view illustrating a second variation of the top plate portion 30C. In the present variation, the top plate portion 30C has the bent portion 303 bent toward another side in the third direction at an end portion on another side in the first direction of the first recessed portion 302A and the second recessed portion 302B, and has a bent portion 304 bent toward another side in the third direction at an end portion on one side in the first direction of the first recessed portion 302A and the second recessed portion 302B.

That is, the top plate portion 30C has the bent portions 303 and 304 that are bent toward another side in the third direction in at least one of an end portion on one side in the first direction and an end portion on another side in the first direction of the first recessed portion 302A and the second recessed portion 302B. By the above, due to an end portion on another side in the third direction of the bent portions 303 and 304, turbulent flow is more likely to be generated in the refrigerant W21 flowing in the vicinity of the second recessed portion 302B on another side in the third direction of the top plate portion 30C, and a refrigerant can more preferentially flow to the base portion 2 side.

### 6. Number of Slits

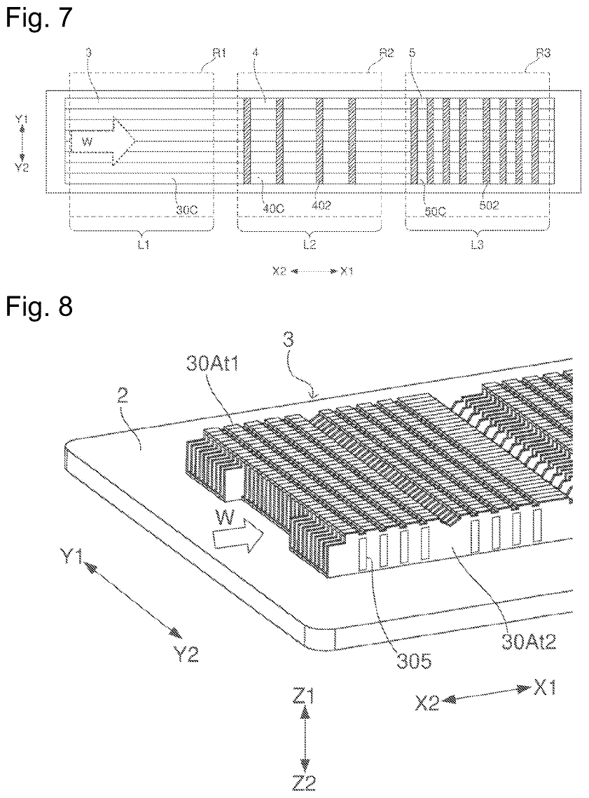

The number of slits provided in the top plate portion as described above will be described with reference to FIG. 7. FIG. 7 is a schematic plan view of the heat dissipation member 1 as viewed from one side in the third direction to another side in the third direction. Note that the heat dissipation member 1 illustrated in FIG. 7 has a configuration different from the configuration illustrated in FIG. 2.

Regions R1, R2, and R3 illustrated in FIG. 7 are regions having the same lengths L1, L2, and L3 in the first direction (L1=L2=L3). The fin groups 3, 4, and 5 are included in the regions R1, R2, and R3, respectively. In the example of FIG. 7, the number of slits included in the region R1 is zero, the number of slits 402 included in the region R2 is four, and the number of slits 502 included in the region R3 is eight.

That is, the number of a plurality of the first recessed portions 302A, 402A, and 502A arranged side by side in the same lengths L1, L2, and L3 in the first direction increases from the upstream side to the downstream side. Due to temperature rise of the refrigerant W, cooling performance becomes lower toward the downstream side. In view of the above, by increasing the number of the first recessed portions toward the downstream side, cooling performance on the downstream side can be improved, and a temperature difference between heating elements (the semiconductor devices 61A and the like) can be reduced from the upstream side to the downstream side.

More specifically, as described above, in a case where the fin groups 3, 4, and 5 are included in the regions R1, R2, and R3, respectively, an open slot is provided between the fin groups 3 and 4 and between the fin groups 4 and 5. By the above, by increasing the number of slits toward the downstream side, cooling performance on the downstream side can be improved by a refrigerant drawn into between the fins from the gap S.

Note that the configuration may be such that only one fin group is provided without providing an open slot, and the number of slits included in regions having the same length in the first direction is increased toward the downstream side. By the above, by increasing the number of slits toward the downstream side, cooling performance on the downstream side can be improved by a refrigerant preferentially flowing to the base portion 2 side between fins.

### 7. Configuration at End Portion in Second Direction of Fin Group

An end portion in the second direction of the fin group may have a configuration below. FIG. 8 is a perspective view illustrating a configuration in the vicinity of the upstream side fin group 3 in the heat dissipation member 1. As illustrated in FIG. 8, a plurality of first slits 305 penetrating in the second direction are formed side by side in the first direction in a side plate portion 30At2 of the fin plate FP arranged at an end portion on another side in the second direction of the upstream side fin group 3. Similarly, a plurality of second slits (not illustrated in FIG. 8) penetrating in the second direction are formed side by side in the first direction in a side plate portion 30At1 of the fin plate FP arranged at an end portion on one side in the second direction of the upstream side fin group 3. The first slit 305 has a third recessed portion recessed toward one side in the second direction. The second slit has a third recessed portion recessed toward another side in the second direction.

That is, the side plate portions 30At2 and 30At1 arranged at both ends in the second direction in the fin group 3 have a third recessed portion recessed inward in the second direction and arranged side by side in the first direction. According to such a configuration, due to a corner portion in the third recessed portion, turbulent flow is generated in the vicinity of the third recessed portion, and flow path resistance on both outer sides in the second direction of the fin group 3 increases.

Therefore, a flow rate of the refrigerant W flowing into the fin group 3 increases, and cooling performance can be improved.

Note that, also in the fin groups 4 and 5, a slit may be provided at both end portions in the second direction similarly to the fin group 3.

### 8. Spoiler

As illustrated in FIG. 3, the first fin plate FP1 is provided with the spoiler 8. Here, the spoiler 8 will be described in detail. Note that, also in the second fin plate FP2, the spoiler 8 is provided similarly to the first fin plate FP1.

In the configuration illustrated in FIG. 3, a single spoiler in which only one of the spoiler 8 is provided is formed in the fin 40, and a double spoiler in which two of the spoilers 8 are provided is also formed in addition to the single spoiler in the fin 50.

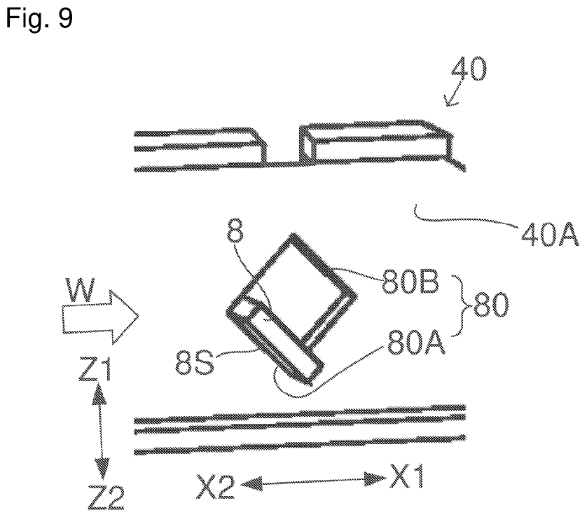

FIG. 9 is an enlarged perspective view illustrating a configuration example of a single spoiler. The through hole 80 penetrates the side plate portion 40A of the fin 40 in the second direction. The through hole 80 has a rectangular shape. The through hole 80 has a pair of facing sides 80A and 80B inclined to one side in the first direction and another side in the third direction. The side 80A is located further on another side in the first direction than the side 80B. The spoiler 8 is formed by being bent to another side in the second direction on the side 80A. The through hole 80 and the spoiler 8 can be formed by making a cut in the side plate portion 40A.

The spoiler 8 includes a facing surface 8S facing a direction in which the refrigerant W flows, that is, one side in the first direction. The spoiler 8 has a function of interrupting flow of the refrigerant W by the facing surface 8S. Turbulent flow of the refrigerant W is easily generated in the vicinity of the facing surface 8S, and cooling performance by the fin 40 can be improved. Further, the spoiler 8 is inclined to one side in the first direction and another side in the third direction. This makes it possible to guide the refrigerant W to the base portion 2 side by the spoiler 8, and cooling performance can be improved.

Note that the single spoiler may have a configuration in which the spoiler 8 is provided on the side 80B side, in addition to the configuration illustrated in FIG. 9. Further, in the double spoiler, the spoiler 8 is provided on both the sides 80A and 80B.

As described above, the fins 40 and 50 have the spoiler 8 projecting in the second direction from the side plate portions 40A and 50A. Since turbulent flow is generated in the vicinity of the spoiler 8, cooling performance of the fins 40 and 50 can be further improved.

Further, as illustrated in FIG. 3, in the fin 40, three of the single spoilers, that is, three of the spoilers 8 are provided. In the fin 50, two of the single spoilers and two of the double spoilers are provided, and six in total of the spoilers 8 are provided.

That is, the number of the spoilers 8 included in each of a plurality of the fins 40 and 50 arranged in the first direction increases toward one side in the first direction. By the above, cooling performance can be improved in the fin 50 on the downstream side where cooling performance is more required.

### 9. Others

The embodiment of the present disclosure is described above. Note that the scope of the present disclosure is not limited to the above embodiment. The present disclosure can be implemented by making various changes to the above embodiment without departing from the gist of the invention. Further, the matters described in the above embodiment can be optionally combined together, as appropriate, as long as there is no inconsistency.

For example, the fin group is not limited to a stacked fin, and a plurality of pin fins projecting in a columnar shape from the base portion 2 to one side in the third direction may be arranged side by side. In this case, a top plate portion is provided at an end portion on one side in the third direction of the pin fin.

Further, for example, a vapor chamber or a heat pipe may be provided between a heating element and a heat dissipation member.

The present disclosure can be used for cooling various heating elements.

1. A heat dissipation member installable in a liquid cooling jacket, the heat dissipation member comprising:
a plate-shaped base portion that extends in a first direction along a direction in which a refrigerant flows and a second direction orthogonal to the first direction, and has thickness in a third direction orthogonal to the first direction and the second direction;
one or a plurality of fin groups arranged side by side in the first direction, the fin group including a plurality of fins projecting from the base portion to one side in the third direction and arranged side by side in the second direction; and
a top plate portion provided at an end portion on one side in the third direction of the fin, wherein
a gap in the third direction is provided between the top plate portion and a top surface of the liquid cooling jacket that can be arranged on one side in the third direction of the top plate portion, and
the top plate portion has a plurality of first recessed portions that are recessed from a surface on one side in the third direction of the top plate portion to another side in the third direction and are arranged side by side in the first direction.

2. The heat dissipation member according to claim 1, wherein
the top plate portion includes a plurality of second recessed portions that are recessed from a surface on another side in the third direction of the top plate portion to one side in the third direction and are arranged side by side in the first direction.

3. The heat dissipation member according to claim 2, wherein
the first recessed portion and the second recessed portion are coupled in a third direction.

4. The heat dissipation member according to claim 3, wherein
the top plate portion includes a bent portion that is bent toward another side in the third direction in at least one of an end portion on one side in the first direction and an end portion on another side in the first direction of the first recessed portion and the second recessed portion.

5. The heat dissipation member according to claim 1, wherein
a number of the plurality of first recessed portions arranged side by side with a same length in the first direction increases from an upstream side toward a downstream side.

6. The heat dissipation member according to claim 1, wherein
the fin includes a side plate portion having a flat plate shape, the side plate portion extending in the first direction and the third direction and having thickness in the second direction, and
the top plate portion is bent in the second direction at an end portion on one side in the third direction of the side plate portion.

7. The heat dissipation member according to claim 6, wherein
the side plate portion arranged at both ends in the second direction in the fin group has a plurality of third recessed portions recessed inward in the second direction and arranged side by side in the first direction.

8. The heat dissipation member according to claim 6, wherein
the fin includes a spoiler projecting in the second direction from the side plate portion.

9. A cooling device comprising:
the heat dissipation member according to claim 1; and
a liquid cooling jacket that accommodates the heat dissipation member.

10. A semiconductor module comprising:
the heat dissipation member according to claim 1; and
at least one semiconductor device arranged on another side in the third direction of the base portion.
